(19) United States
(12) Patent Application Publication
(10) Pub. No.: US 2026/0130033 A1
(43) Pub. Date: May 7, 2026

(54) ELECTRONIC DEVICE

(71) Applicant: InnoLux Corporation, Miao-Li County (TW)

(72) Inventors: Yi-Hung LIN, Miao-Li County (TW); Hong-Kang CHANG, Miao-Li County (TW); Tsan-Chu LU, Miao-Li County (TW)

(21) Appl. No.: 19/352,321

(22) Filed: Oct. 7, 2025

(30) Foreign Application Priority Data
Nov. 7, 2024 (CN) 202411580603.3

(51) Int. Cl. H10H 29/49; H10H 29/34; H10K 59/131; H10K 59/35

(52) U.S. Cl. CPC H10H 29/49; H10H 29/34; H10K 59/131; H10K 59/353

(57) ABSTRACT

An electronic device includes: a substrate; a scan line disposed on the substrate and used to output a first signal; a first data line disposed on the substrate and intersecting with the scan line, wherein the first data line is used to output a second signal; a first sub-pixel disposed on the substrate and receiving the first signal and the second signal; and a second sub-pixel disposed on the substrate and receiving the first signal and the second signal, wherein a color of the first sub-pixel is the same as a color of the second sub-pixel.

### CROSS-REFERENCE TO RELATED APPLICATIONS

This application claims the benefits of the Chinese Patent Application Ser. No. 202411580603.3, filed on Nov. 7, 2024, the subject matter of which is incorporated herein by reference.

### BACKGROUND

### Field

The present disclosure relates to an electronic device. More specifically, the present disclosure relates to an electronic device with a plurality of sub-pixels.

### Description of Related Art

With the advancement of technology and in order to meet the needs of consumers, the market has continuously improved the display quality or contrast of electronic devices. However, current electronic devices still have display quality issues. For example, large electronic devices are prone to have quality defects such as graininess when displaying images.

Therefore, it is desirable to provide an electronic device to improve the display quality problem of electronic devices.

### SUMMARY

The present disclosure provides an electronic device, comprising: a substrate; a scan line disposed on the substrate and used to output a first signal; a first data line disposed on the substrate and intersecting with the scan line, wherein the first data line is used to output a second signal; a first sub-pixel disposed on the substrate and receiving the first signal and the second signal; and a second sub-pixel disposed on the substrate and receiving the first signal and the second signal, wherein a color of the first sub-pixel is the same as a color of the second sub-pixel.

Other novel features of the disclosure will become more apparent from the following detailed description when taken in conjunction with the accompanying drawings.

### BRIEF DESCRIPTION OF DRAWINGS

FIG. 1A is a schematic view of a part of an electronic device according to one embodiment of the present disclosure.

FIG. 1B is a partial enlarging view of FIG. 1A.

FIG. 2 is an enlarging schematic view of a part of an electronic device according to one embodiment of the present disclosure.

FIG. 3 is an enlarging schematic view of a part of an electronic device according to one embodiment of the present disclosure.

FIG. 4 is an enlarging schematic view of a part of an electronic device according to one embodiment of the present disclosure.

FIG. 5 is an enlarging schematic view of a part of an electronic device according to one embodiment of the present disclosure.

FIG. 6 is an enlarging schematic view of a part of an electronic device according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification.

The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

In the present disclosure, the thickness, the length, the width, or the distance and angle between elements may be measured by using an optical microscope (OM), scanning electron microscope (SEM), film thickness profiler (α-step), ellipsometer, or other suitable methods. More specifically, according to some embodiments, a scanning electron microscope can be used to obtain a cross-sectional image of the structure and measure the thickness, length, width of each element or the distance and angle between elements. Furthermore, any two values or directions used for comparison may have a certain error. If the first value is equal to the second value, it implies that there may be an error of about 10% between the first value and the second value. If the first direction is perpendicular to the second direction, the angle between the first direction and the second direction may be between 80°and 100°. If the first direction is parallel to the second direction, the angle between the first direction and the second direction may be between 0°and 10°.

The embodiments of the present disclosure can be understood in conjunction with the drawings, and the drawings of the present disclosure are also considered as a part of the disclosure. It should be understood that the drawings of the present disclosure are not drawn to scale, and in fact, the sizes of elements may be arbitrarily enlarged or reduced in order to clearly illustrate the features of the present disclosure.

It should be noted that the technical solutions provided in the following different embodiments can be replaced, combined or mixed with each other to form another embodiment without violating the spirit of the present disclosure.

The electronic device of the present disclosure may comprise, for example, a display device, a sensing device, an antenna device, a touch device, a tiled device or other suitable electronic device, but the present disclosure is not limited thereto. The display device of the present disclosure may be a non-self-luminous display device or self-luminous display device, such as a liquid crystal display, a cholesteric liquid crystal display, an electro-phoretic display, an organic light emitting diode display, and a light emitting diode display, but the present disclosure is not limited thereto. The display device may include a light emitting diode, a light conversion layer or other suitable materials, or a combination thereof, but the present disclosure is not limited thereto. The light emitting diode may comprise, for example, an organic light emitting diode (OLED), a mini LED, a micro LED, a quantum dot LED (which may comprise a QLED or a QDLED), but the present disclosure is not limited thereto. The light conversion layer may comprise a wavelength conversion material and/or a filter material. The light conversion material may comprise, for example, fluorescence, phosphors, quantum dots (QDs), other suitable material or a combination thereof, but the present disclosure is not limited thereto. The sensing device may include, for example, a biometric sensor, a touch sensor, a fingerprint sensor, an optical sensor, an infrared sensor, a temperature sensor, other suitable sensors, or a combination of the above types of sensors. The antenna device may be, for example, a liquid crystal antenna or other types of antenna types, but is not limited thereto. The tiled device may, for example, include a tiled display device or a tiled antenna device, but is not limited thereto. The electronic device may include electronic components, which may include passive components, active components, or a combination thereof, such as capacitors, resistors, inductors, varactor diodes, variable capacitors, filters, diodes, transistors, sensors, micro-electromechanical system components (MEMS), chips, etc., but are not limited thereto. It should be noted that the electronic device disclosed herein may be various combinations of the above devices, but is not limited thereto.

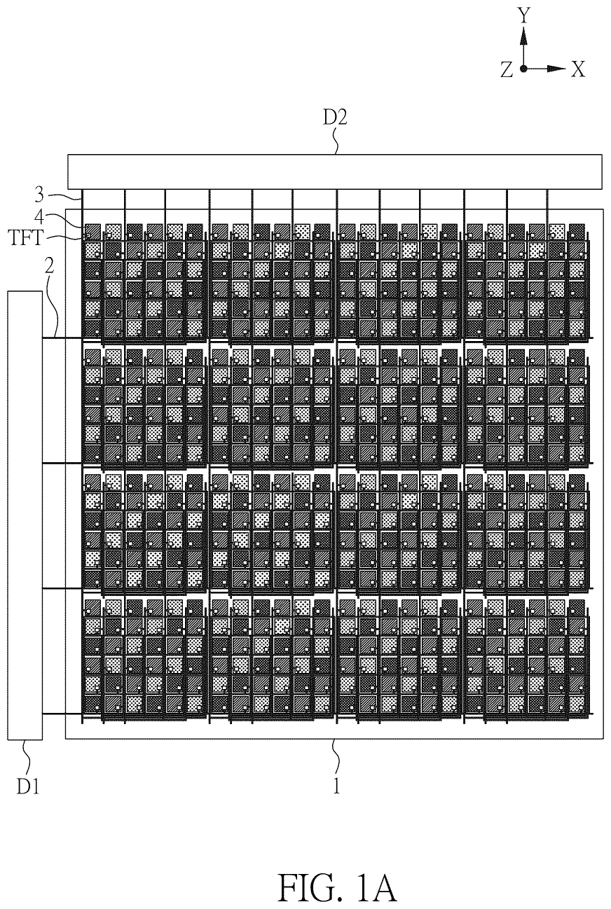

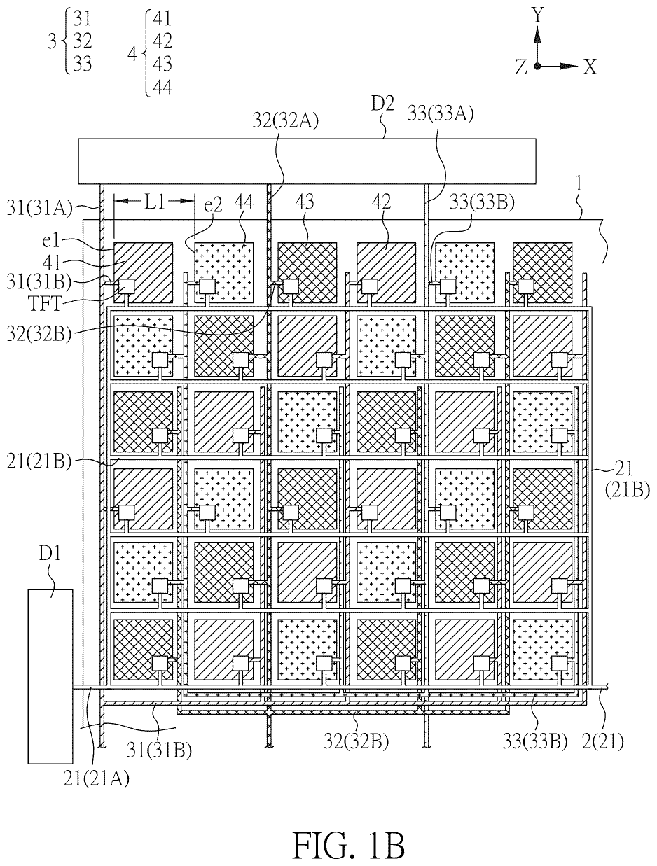

FIG. 1A is a schematic view of a part of an electronic device according to one embodiment of the present disclosure. FIG. 1B is a partial enlarging view of FIG. 1A.

In one embodiment of the present disclosure, as shown in FIG. 1A and FIG. 1B, the electronic device comprises: a substrate 1; a plurality of scan lines 2 disposed on the substrate 1 and extending along a first direction X, wherein the plurality of scan lines 2 comprise a scan line 21; a plurality of data lines 3 disposed on the substrate 1, extending along a second direction Y and intersecting with the plurality of scan lines 2, wherein “intersecting” refers to that the extension direction of the scan lines 2 is different from the extension direction of the data lines 3 in some embodiments; the first direction X is different from the second direction Y and the plurality of data lines 3 comprises a first data line 31 in some embodiments; and a plurality of sub-pixels 4 disposed on the substrate 1 and comprising a first sub-pixel 41 and a second sub-pixel 42. The scan line 21 is used to output a first signal (for example, a scan signal), and the first data line 31 is used to output a second signal (for example, a data signal). The first sub-pixel 41 may receive the first signal and the second signal, and the second sub-pixel 42 may receive the first signal and the second signal, wherein a color of the first sub-pixel 41 is the same as a color of the second sub-pixel 42. In one embodiment of the present disclosure, the same fill pattern in FIG. 1A and FIG. 1B represents sub-pixels with the same color. Taking the top left sub-pixel in FIG. 1B as the first sub-pixel 41 as an example, the remaining sub-pixels with the same filling pattern may be the second sub-pixels 42, but the present disclosure is not limited thereto.

In the present disclosure, as shown in FIG. 1A and FIG. 1B, the plurality of data lines 3 further comprise a second data line 32 disposed on the substrate 1, wherein the second data line 32 is used to output a third signal (for example, a data signal). The plurality of sub-pixels 4 further comprise a third sub-pixel 43 disposed on the substrate 1 and locating between the first sub-pixel 41 and the second sub-pixel 42. The color of the third sub-pixel 43 is different from the color of the first sub-pixel 41, and the third sub-pixel 43 may receive the first signal and the third signal.

In the present disclosure, as shown in FIG. 1A and FIG. 1B, the plurality of data lines 3 further comprise a third data line 33 disposed on the substrate 1, wherein the third data line 33 is used to output a fourth signal (for example, a data signal). The plurality of sub-pixels 4 further comprise a fourth sub-pixel 44 disposed on the substrate 1 and locating between the first sub-pixel 41 and the second sub-pixel 42, and the fourth sub-pixel 44 may receive the first signal and the fourth signal, wherein the color of the fourth sub-pixel 44 is different from the color of the first sub-pixel 41, and the color of the fourth sub-pixel 44 is different from the color of the third sub-pixel 43.

In one embodiment of the present disclosure, the first sub-pixel 41 and the second sub-pixel 42 may be, for example, red sub-pixels, the third sub-pixel 43 may be, for example, a blue sub-pixel, and the fourth sub-pixel 44 may be, for example, a green sub-pixel, but the present disclosure is not limited thereto. The first sub-pixel 41 and the second sub-pixel 42 may be driven by receiving the first signal and the second signal through the scan line 21 and the first data line 31, the third sub-pixel 43 may be driven by receiving the first signal and the third signal through the scan line 21 and the second data line 32, and the fourth sub-pixel 44 may be driven by receiving first signal and the fourth signal through the scan line 21 and the third data line 33, thereby allowing the electronic device to display images.

In one embodiment of the present disclosure, as shown in FIG. 1A and FIG. 1B, the plurality of sub-pixels 4 are arranged in an array. More specifically, FIG. 1A is an example of a 4×4 array of pixels, and each pixel may comprise sub-pixels 4 arranged in a 6×6 array as shown in FIG. 1B.

Thus, the sub-pixels 4 in FIG. 1A are arranged in a 24×24 array, but the present disclosure is not limited thereto, and the number and arrangement of the sub-pixels 4 may be adjusted according to the needs. In the present disclosure, in the first direction X, the number of the sub-pixels 4 may be greater than the number of the data lines 3. For example, as shown in FIG. 1A, there are 24 sub-pixels 4 and there are 12 data lines 3 in the first direction X. As shown in FIG. 1B, there are 6 sub-pixels 4 and there are 3 data lines 3 in the first direction X, but the present disclosure is not limited thereto. In the present disclosure, in the second direction Y, the number of the sub-pixels 4 may be greater than the number of the scan lines 2. For example, as shown in FIG. 1A, there are 24 sub-pixels 4 and there are 4 scan lines 2 in the second direction Y. As shown in FIG. 1B, there are 6 sub-pixels 4 and there is one scan line 2 in the second direction Y, but the present disclosure is not limited thereto. Through the above design, the display quality of the electronic device can be improved. In the present disclosure, the number of the data line 3 is calculated based on the number of one end of the data line 3 connected to a second driving unit D2. In the present disclosure, the number of the scan line 2 is calculated based on the number of one end of the scan line 2 connected to a first driving unit D1.

In one embodiment of the present disclosure, the length L1 of the sub-pixel 4 (for example, the first sub-pixel 41, the second sub-pixel 42, the third sub-pixel 43 or the fourth sub-pixel 44) may be defined as the distance from an edge of a sub-pixel 4 to the same edge of another adjacent sub-pixel 4.

For example, as shown in FIG. 1B, the first sub-pixel 41 may be adjacent to the fourth sub-pixel 44, the length L1 of the first sub-pixel 41 may be the distance from an edge e1 of the first sub-pixel 41 to the same edge e2 of the adjacent fourth sub-pixel 44. In one embodiment of the present disclosure, in the extension direction of the scan line 2 (for example, the first direction X), the length L1 of the sub-pixel 4 (for example, the first sub-pixel 41, the second sub-pixel 42, the third sub-pixel 43 or the fourth sub-pixel 44) may be greater than or equal to 0.1 mm and less than or equal to 10 mm (that is, 0.1 mm≤L1≤10 mm). For example, the length L1 of the sub-pixel 4 (for example, the first sub-pixel 41, the second sub-pixel 42, the third sub-pixel 43 or the fourth sub-pixel 44) may be greater than or equal to (⅙) mm and less than or equal to 5 mm (that is, ⅙ mm≤L1≤5 mm), or the length L1 of the sub-pixel 4 (for example, the first sub-pixel 41, the second sub-pixel 42, the third sub-pixel 43 or the fourth sub-pixel 44) may be greater than or equal to (⅓) mm and less than or equal to 3 mm (that is ⅓ mm≤L1≤3 mm), but the present disclosure is not limited thereto.

In one embodiment of the present disclosure, as shown in FIG. 1B, the scan line 21 may comprise a first portion 21A and a second portion 21B connected to the first portion 21A, wherein the first portion 21A is electrically connected to a first driving unit D1, and the second portion 21B is electrically connected to the first sub-pixel 41 and/or the second sub-pixel 42. More specifically, the first portion 21A of the scan line 21 may be directly connected to the first driving unit D1, and the second portion 21B of the scan line 21 may be respectively connected to the first portion 21A and the first sub-pixel 41 and/or the second sub-pixel 42. Thus, the first driving unit D1 may output the first signal through the first portion 21A of the scan line 21, and the first sub-pixel 41 and the second sub-pixel 42 may receive the first signal through the second portion 21B of the scan line 21, thereby transmitting the scan signal from the first driving unit D1 to the first sub-pixel 41 and the second sub-pixel 42. The second portion 21B of the scan line 21 may also be electrically connected to the third sub-pixel 43 and the fourth sub-pixel 44, thereby transmitting the first signal (for example, the scan signal) from the first driving unit D1 to the third sub-pixel 43 and the fourth sub-pixel 44. In the present disclosure, the number and the extension direction of the second portion 21B of the scan line 21 are not particularly limited, and may be adjusted according to the design of the sub-pixel 4. In one embodiment of the present disclosure, the number of the scan line 2 may be calculated based on the number of the first portion 21A of the scan line 2 connected to the first driving unit D1.

In one embodiment of the present disclosure, as shown in FIG. 1A and FIG. 1B, the first data line 31 may comprise a third portion 31A and a fourth portion 31B connected to the third portion 31A, wherein the third portion 31A is electrically connected to a second driving unit D2, and the fourth portion 31B is electrically connected to the first sub-pixel 41 and/or the second sub-pixel 42. More specifically, the third portion 31A of the first data line 31 may be directly connected to the second driving unit D2, and the fourth portion 31B of the first data line 31 may be respectively connected to the third portion 31A and the first sub-pixel 41 and/or the second sub-pixel 42. Thus, the second driving unit D2 may output the second signal through the third portion 31A of the first data line 31, and the first sub-pixel 41 and the second sub-pixel 42 may receive the second signal through the fourth portion 31B of the first data line 31, thereby transmitting the second signal (for example, the data signal) from the second driving unit D2 to the first sub-pixel 41 and the second sub-pixel 42. In the present disclosure, the number and the extension direction of the fourth portion 31B of the first data line 31 are not particularly limited and may be adjusted according to the design of the sub-pixel 4.

Similarly, the second data line 32 may comprise a fifth portion 32A and a sixth portion 32B connected to the fifth portion 32A, wherein the fifth portion 32A is electrically connected to the second driving unit D2, and the sixth portion 32B is electrically connected to the third sub-pixel 43. More specifically, the fifth portion 32A of the second data line 32 may be directly connected to the second driving unit D2, and the sixth portion 32B of the second data line 32 may be respectively connected to the fifth portion 32A and the third sub-pixel 43. Thus, the second driving unit D2 may output the third signal through the fifth portion 32A of the second data line 32, and the third sub-pixel 43 may receive the third signal through the sixth portion 32B of the second data line 32, thereby transmitting the third signal (for example, the data signal) from the second driving unit D2 to the third sub-pixel 43. In the present disclosure, the number and the extension direction of the sixth portion 32B of the second data line 32 are not particularly limited and may be adjusted according to the design of the sub-pixel 4.

Similarly, the third data line 33 may comprise a seventh portion 33A and an eighth portion 33B connected to the seventh portion 33A, wherein the seventh portion 33A is electrically connected to the second driving unit D2, and the eighth portion 33B is electrically connected to the fourth sub-pixel 44. More specifically, the seventh portion 33A of the third data line 33 may be directly connected to the second driving unit D2, and the eighth portion 33B of the third data line 33 may be respectively connected to the seventh portion 33A and the fourth sub-pixel 44. Thus, the second driving unit D2 may output the fourth signal through the seventh portion 33A of the third data line 33, and the fourth sub-pixel 44 may receive the fourth signal through the eighth portion 33B of the third data line 33, thereby transmitting the fourth signal (for example, the data signal) from the second driving unit D2 to the fourth sub-pixel 44. In the present disclosure, the number and the extension direction of the eighth portion 33B of the third data line 33 are not particularly limited and may be adjusted according to the design of the sub-pixel 4. In one embodiment of the present disclosure, the number of the data line 3 may be calculated based on the number of the third portion 31A of the first data line 31, the fifth portion 32A of the second data line 32 and the seventh portion 33A of the third data line 33 connected to the second driving unit D2.

In one embodiment of the present disclosure, as shown in FIG. 1A, the first driving unit D1 and the second driving unit D2 may be disposed adjacent to the substrate 1 respectively. In other embodiments, the first driving unit D1 and the second driving unit D2 may be selectively disposed on the substrate 1.

In one embodiment of the present disclosure, the electronic device may comprise a plurality of transistors TFT, selectively disposed in the sub-pixel 4. The transistor TFT may be electrically connected to the scan line 2 and the data line 3 respectively to be used as a switch transistor to drive the sub-pixel 4. For example, as shown in FIG. 1A and FIG. 1B, each sub-pixel 4 may comprise a transistor TFT, and the transistor TFT may be electrically connected to the corresponding scan line 2 and the corresponding data line 3 respectively to drive the corresponding sub-pixel 4, but the present disclosure is not limited thereto. In one embodiment of the present disclosure, the number of the transistors TFT may be equal to the number of the sub-pixels 4, but the present disclosure is not limited thereto.

In the present disclosure, the substrate 1 may be a rigid substrate or a flexible substrate, and suitable material thereof may comprise glass, quartz, sapphire, ceramics, plastics, polycarbonate (PC), polyimide (PI), polypropylene (PP), polyethylene terephthalate (PET), polymethylmethacrylate (PMMA), other suitable material or a combination thereof, but the present disclosure is not limited thereto. In the present disclosure, the material of the scan line 2 and the data line 3 may respectively comprise a metal, a metal oxide, an alloy thereof or a combination thereof, and for example, may comprise gold, silver, copper, palladium, platinum, ruthenium, aluminum, cobalt, nickel, titanium, molybdenum, manganese, tungsten, indium zinc oxide (IZO), indium tin oxide (ITO), indium tin zinc oxide (ITZO), indium gallium zinc oxide (IGZO), aluminum zinc oxide (AZO) or a combination thereof, but the present disclosure is not limited thereto. In the present disclosure, the transistors TFT may respectively comprise a semiconductor material, and suitable semiconductor material may comprise amorphous silicon, polycrystalline silicon (such as low temperature polycrystalline silicon (LTPS)) or oxide semiconductors (such as indium gallium zinc oxide (IGZO) or indium gallium oxide (IGO)), but the present disclosure is not limited thereto.

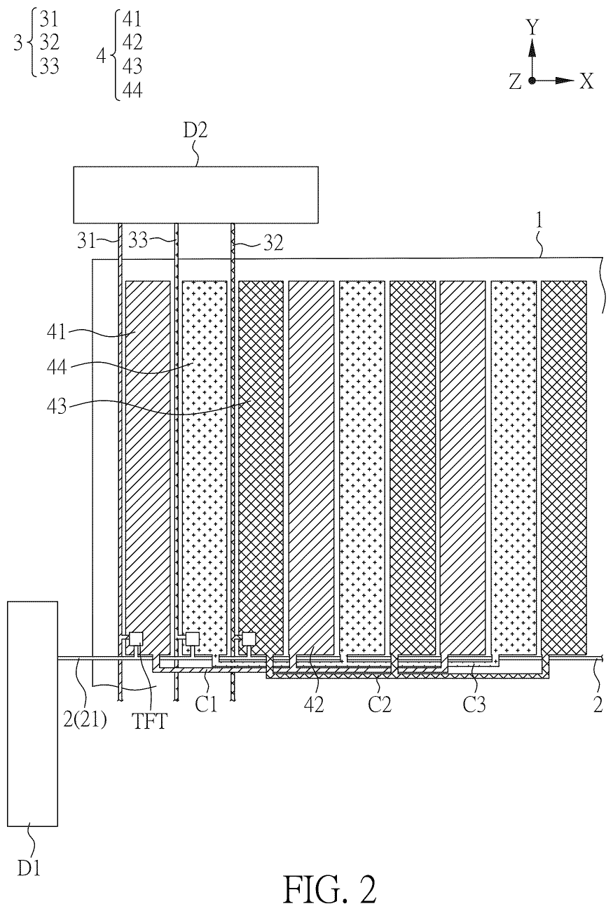

FIG. 2 is an enlarging schematic view of a part of an electronic device according to one embodiment of the present disclosure. The electronic device of FIG. 2 is similar to that of FIG. 1B, except for the following differences. In addition, the same fill pattern represents sub-pixels with the same color in FIG. 2. Taking the sub-pixel on the left side of FIG. 2 as the first sub-pixel as an example, the remaining sub-pixels with the same fill pattern can be the second sub-pixels, but the present disclosure is not limited thereto.

In one embodiment of the present disclosure, each pixel in the electronic device may comprise, for example, sub-pixels 4 arranged in a 1×9 array as shown in FIG. 2, but the present disclosure is not limited thereto, and the number and arrangement of the sub-pixels 4 may be adjusted according to the needs. In one embodiment of the present disclosure, in the first direction X, the number of the sub-pixels 4 may be greater than the number of the data lines 3. For example, as shown in FIG. 2, there are 9 sub-pixels 4 and there are 3 data lines 3 in the first direction X. Through the above design, the display quality of the electronic device can be improved.

In the present disclosure, the number of the data line 3 is calculated based on the number of one end of the data line 3 connected to the second driving unit D2.

In one embodiment of the present disclosure, as shown in FIG. 2, the number of the transistors TFT may be less than the number of the sub-pixels 4. More specifically, the transistor TFT may be respectively disposed in the first sub-pixel 41, one of the third sub-pixel 43 and one of the fourth sub-pixel 44. The transistor TFT may be electrically connected to the scan line 2 and the data line 3 respectively to be used as a switch transistor to drive the sub-pixels 4 with the same color in the same pixel.

In one embodiment of the present disclosure, the first sub-pixel 41 and the second sub-pixel 42 may be, for example, red sub-pixels, the third sub-pixel 43 may be, for example, a blue sub-pixel, and the fourth sub-pixel 44 may be, for example, a green sub-pixel, but the present disclosure is not limited thereto. The first sub-pixel 41 and the second sub-pixel 42 may be driven by receiving the first signal and the second signal through the scan line 21 and the first data line 31, the third sub-pixel 43 may be driven by receiving the first signal and the third signal through the scan line 21 and the second data line 32, and the fourth sub-pixel 44 may be driven by receiving the first signal and the fourth signal through the scan line 21 and the third data line 33, thereby allowing the electronic device to display images.

In one embodiment of the present disclosure, as shown in FIG. 2, the first sub-pixel 41 and the second sub-pixel 42 are electrically connected through a first connection line C1. The first data line 31 may output the second signal to the first sub-pixel 41, and the second signal is then transmitted to the second sub-pixels 42 through the first connection line C1. Similarly, the third sub-pixels 43 may be electrically connected through a second connection line C2. The second data line 32 may output the third signal to one of the third sub-pixels 43, and the third signal is then transmitted to other third sub-pixels 43 through the second connection line C2. In addition, the fourth sub-pixels 44 may be electrically connected through a third connection line C3. The third data line 33 may output the fourth signal to one of the fourth sub-pixels 44, and the fourth signal is then transmitted to other fourth sub-pixels 44 through a third connection line C3.

In the present disclosure, other detail features of the electronic device may be referred to those of FIG. 1A and FIG. 1B, and are not described again here.

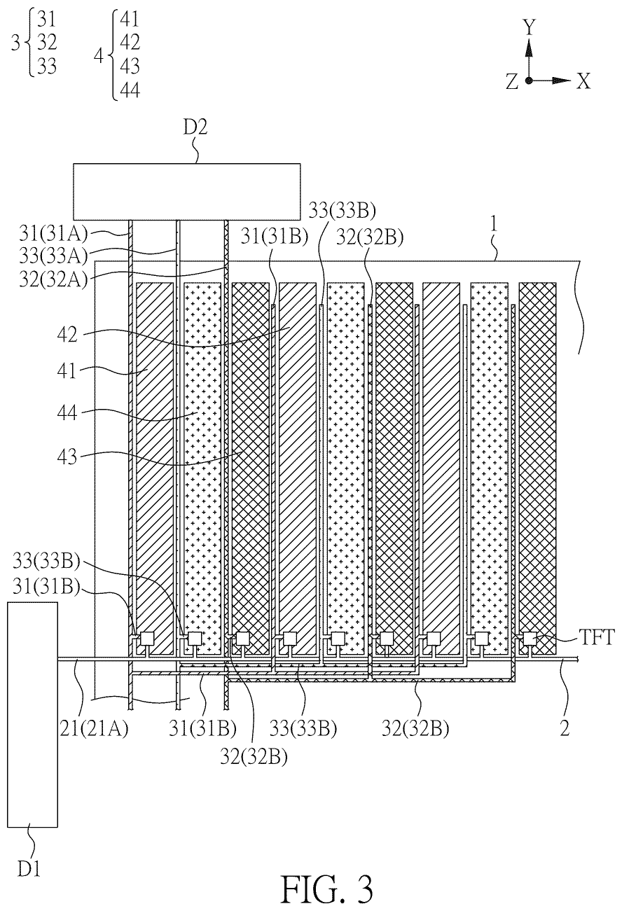

FIG. 3 is an enlarging schematic view of a part of an electronic device according to one embodiment of the present disclosure. The electronic device of FIG. 3 is similar to that of FIG. 1B, except for the following differences. In addition, the same fill pattern represents sub-pixels with the same color in FIG. 3. Taking the sub-pixel on the left side of FIG. 3 as the first sub-pixel as an example, the remaining sub-pixels with the same fill pattern can be the second sub-pixels, but the present disclosure is not limited thereto.

In one embodiment of the present disclosure, each pixel in the electronic device may comprise, for example, sub-pixels 4 arranged in a 1×9 array as shown in FIG. 3, but the present disclosure is not limited thereto, and the number and arrangement of the sub-pixels 4 may be adjusted according to the needs. In one embodiment of the present disclosure, in the first direction X, the number of the sub-pixels 4 may be greater than the number of the data lines 3. For example, as shown in FIG. 3, there are 9 sub-pixels 4 and there are 3 data lines 3 in the first direction X. Through the above design, the display quality of the electronic device can be improved.

In the present disclosure, the number of the data line 3 is calculated based on one end of the data line 3 connected to the second driving unit D2.

In one embodiment of the present disclosure, as shown in FIG. 3, each sub-pixel 4 may comprise a transistor TFT, and the transistor TFT may be electrically connected to the corresponding scan line 2 and the corresponding data line 3 respectively, thereby driving the corresponding sub-pixel 4, but the present disclosure is not limited thereto. In one embodiment of the present disclosure, the number of the transistors TFT may be equal to the number of the sub-pixels 4, but the present disclosure is not limited thereto.

In one embodiment of the present disclosure, the first sub-pixel 41 and the second sub-pixel 42 may be, for example, red sub-pixels, the third sub-pixel 43 may be, for example, a blue sub-pixel, and the fourth sub-pixel 44 may be, for example, a green sub-pixel, but the present disclosure is not limited thereto. The first sub-pixel 41 and the second sub-pixel 42 are driven by receiving the first signal and the second signal through the scan line 21 and the first data line 31, the third sub-pixel 43 may be driven by receiving the first signal and the third signal through the scan line 21 and the second data line 32, and the fourth sub-pixel 44 may be driven by receiving the first signal and the fourth signal through the scan line 21 and the third data line 33, thereby allowing the electronic device to display images.

In one embodiment of the present disclosure, as shown in FIG. 3, the third portion 31A of the first data line 31 may be directly connected to the second driving unit D2, and the fourth portion 31B may be electrically connected to the third portion 31A and the first sub-pixel 41 and/or the second sub-pixel 42 respectively to output the second signal to the first sub-pixel 41 and the second sub-pixel 42. Similarly, the fifth portion 32A of the second data line 32 may be directly connected to the second driving unit D2, and the sixth portion 32B may be electrically connected to the third sub-pixel 43 to output the third signal to the third sub-pixel 43. The seventh portion 33A of the third data line 33 may be directly connected to the second driving unit D2, and the eighth portion 33B may be electrically connected to the fourth sub-pixel 44 to output the fourth signal to the fourth sub-pixel 44.

In the present disclosure, other detail features of the electronic device may be referred to those of FIG. 1A and FIG. 1B, and are not described again here.

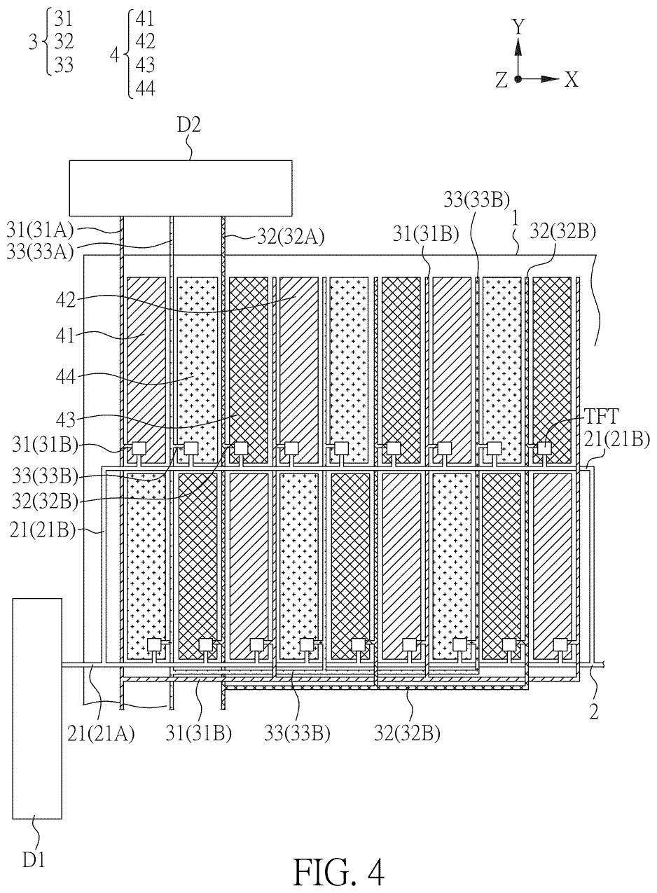

FIG. 4 is an enlarging schematic view of a part of an electronic device according to one embodiment of the present disclosure. The electronic device of FIG. 4 is similar to that of FIG. 1B, except for the following differences. In addition, the same fill pattern represents sub-pixels with the same color in FIG. 4. Taking the sub-pixel on the top left side of FIG. 4 as the first sub-pixel as an example, the remaining sub-pixels with the same fill pattern can be the second sub-pixels, but the present disclosure is not limited thereto.

In one embodiment of the present disclosure, each pixel in the electronic device may comprise, for example, sub-pixels 4 arranged in a 2×9 array as shown in FIG. 4, but the present disclosure is not limited thereto, and the number and arrangement of the sub-pixels 4 may be adjusted according to the needs. In one embodiment of the present disclosure, in the first direction X, the number of the sub-pixels 4 may be greater than the number of the data lines 3. For example, as shown in FIG. 4, there are 9 sub-pixels 4 and there are 3 data lines 3 in the first direction X. In one embodiment of the present disclosure, in the second direction Y, the number of the sub-pixels 4 may be greater than the number of the scan lines 2. For example, as shown in FIG. 4, there are 2 sub-pixels 4 and there is one scan line 2 in the second direction Y. Through the above design, the display quality of the electronic device can be improved. In the present disclosure, the number of the data line 3 is calculated based on the number of one end of the data line 3 connected to a second driving unit D2. In the present disclosure, the number of the scan line 2 is calculated based on the number of one end of the scan line 2 connected to a first driving unit D1.

In one embodiment of the present disclosure, as shown in FIG. 4, each sub-pixel 4 may comprise a transistor TFT, and the transistor TFT may be electrically connected to the corresponding scan line 2 and the corresponding data line 3 respectively, thereby driving the corresponding sub-pixel 4, but the present disclosure is not limited thereto. In one embodiment of the present disclosure, the number of the transistor TFT may be equal to the number of the sub-pixel 4, but the present disclosure is not limited thereto.

In one embodiment of the present disclosure, the first sub-pixel 41 and the second sub-pixel 42 may be, for example, red sub-pixels, the third sub-pixel 43 may be, for example, a blue sub-pixel, and the fourth sub-pixel 44 may be, for example, a green sub-pixel, but the present disclosure is not limited thereto. The first sub-pixel 41 and the second sub-pixel 42 may be driven by receiving the first signal and the second signal through the scan line 21 and the first data line 31, the third sub-pixel 43 may be driven by receiving the first signal and the third signal through the scan line 21 and the second data line 32, and the fourth sub-pixel 44 may be driven by receiving the first signal and the fourth signal through the scan line 21 and the third data line 33, thereby allowing the electronic device to display images.

In one embodiment of the present disclosure, as shown in FIG. 4, the first portion 21A of the scan line 2 may be directly connected to the first driving unit D1, and the second portion 21B may be electrically connected to the first sub-pixel 41, the second sub-pixel 42, the third sub-pixel 43 and/or the fourth sub-pixel 44 respectively to transmit the first signal to the first sub-pixel 41, the second sub-pixel 42, the third sub-pixel 43 and the fourth sub-pixel 44. In one embodiment of the present disclosure, as shown in FIG. 4, the third portion 31A of the first data line 31 may be directly connected to the second driving unit D2, and the fourth portion 31B may be electrically connected to the first sub-pixel 41 and/or the second sub-pixel 42 respectively, to output the second signal to the first sub-pixel 41 and the second sub-pixel 42. Similarly, the fifth portion 32A of the second data line 32 may be directly connected to the second driving unit D2, and the sixth portion 32B may be electrically connected to the third sub-pixel 43 to output the third signal to the third sub-pixel 43. The seventh portion 33A of the third data line 33 may be directly connected to the second driving unit D2, and the eighth portion 33B may be electrically connected to the fourth sub-pixel 44 to output the fourth signal to the fourth sub-pixel 44.

In the present disclosure, other detail features of the electronic device may be referred to those of FIG. 1A and FIG. 1B, and are not described again here.

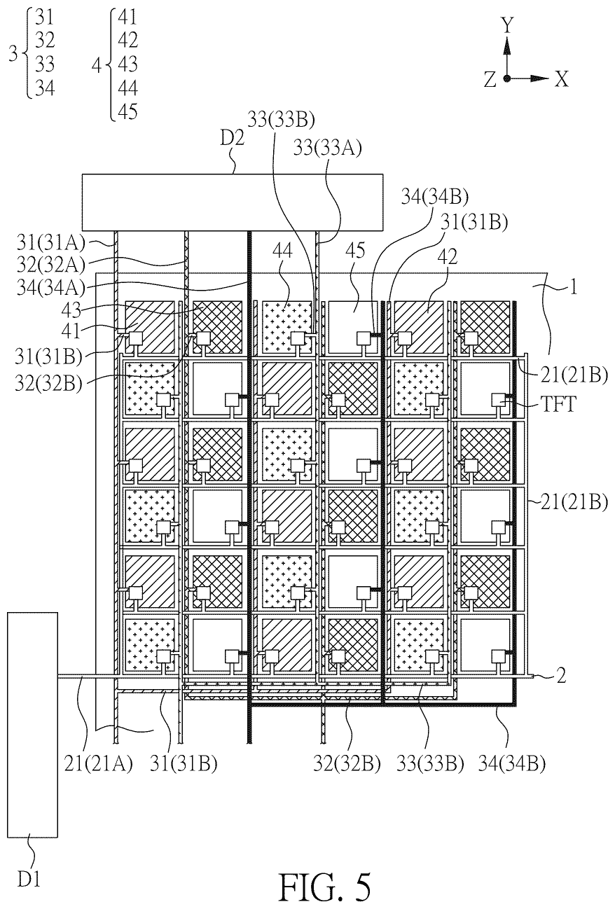

FIG. 5 is an enlarging schematic view of a part of an electronic device according to one embodiment of the present disclosure. The electronic device of FIG. 5 is similar to that of FIG. 1B, except for the following differences. In addition, the same fill pattern represents sub-pixels with the same color in FIG. 5. Taking the sub-pixel on the top left side of FIG. 5 as the first sub-pixel as an example, the remaining sub-pixels with the same fill pattern can be the second sub-pixels, but the present disclosure is not limited thereto.

In one embodiment of the present disclosure, as shown in FIG. 5, the plurality of data lines 3 further comprise a fourth data line 34 disposed on the substrate 1, wherein the fourth data line 34 is used to output a fifth signal (for example, a data signal). The plurality of sub-pixels 4 may further comprise a fifth sub-pixel 45 disposed on the substrate 1 and locating between the first sub-pixel 41 and the second sub-pixel 42, and the fifth sub-pixel 45 may receive the first signal and the fifth signal. Herein, the color of the fifth sub-pixel 45 may be different from the color of the first sub-pixel 41, the color of the fifth sub-pixel 45 may be different from the color of the third sub-pixel 43, and the color of the fifth sub-pixel 45 may be different from the color of the fourth sub-pixel 44.

In one embodiment of the present disclosure, the first sub-pixel 41 and the second sub-pixel 42 may be, for example, red sub-pixels, the third sub-pixel 43 may be, for example, a blue sub-pixel, the fourth sub-pixel 44 may be, for example, a green sub-pixel, and the fifth sub-pixel 45 may be, for example, a white sub-pixel, but the present disclosure is not limited thereto. The first sub-pixel 41 and the second sub-pixel 42 may be driven by receiving the first signal and the second signal through the scan line 21 and the first data line 31, the third sub-pixel 43 may be driven by receiving the first signal and the third signal through the scan line 21 and the second data line 32, the fourth sub-pixel 44 may be driven by receiving the first signal and the fourth signal through the scan line 21 and the third data line 33, and the fifth sub-pixel 45 may be driven by receiving the first signal and the fifth signal through the scan line 21 and the fourth data line 34, thereby allowing the electronic device to display images.

In one embodiment of the present disclosure, each pixel in the electronic device may comprise, for example, sub-pixels 4 arranged in a 6×6 array as shown in FIG. 5, but the present disclosure is not limited thereto, and the number and arrangement of the sub-pixels 4 may be adjusted according to the needs. In one embodiment of the present disclosure, in the first direction X, the number of the sub-pixels 4 may be greater than the number of the data lines 3. For example, as shown in FIG. 5, there are 6 sub-pixels 4 and there are 4 data lines 3 in the first direction X. In one embodiment of the present disclosure, in the second direction Y, the number of the sub-pixel 4 may be greater than the number of the scan line 2. For example, as shown in FIG. 5, there are 6 sub-pixels 4 and there is one scan line 2 in the second direction Y. Through the above design, the display quality of the electronic device can be improved. In the present disclosure, the number of the data lines 3 is calculated based on the number of one end of the data line 3 connected to the second driving unit D2. In the present disclosure, the number of the scan line 2 is calculated based on the number of one end of the scan line 2 connected to the first driving unit D1.

In one embodiment of the present disclosure, as shown in FIG. 5, the fourth data line 34 may comprise a ninth portion 34A and a tenth portion 34B connected to the ninth portion 34A, wherein the ninth portion 34A is electrically connected to the second driving unit D2 and the tenth portion 34B is electrically connected to the fifth sub-pixel 45. More specifically, the ninth portion 34A of the fourth data line 34 may be directly connected to the second driving unit D2, and the tenth portion 34B of the fourth data line 34 may be electrically connected to the ninth portion 34A and the fifth sub-pixel 45 respectively. Thus, the second driving unit D2 may output the fifth signal through the ninth portion 34A of the fourth data line 34, and the fifth sub-pixel 45 may receive the fifth signal through the tenth portion 34B of the fourth data line 34, thereby transmitting the fifth signal (for example, the data signal) from the second driving unit D2 to the fifth sub-pixel 45. In the present disclosure, the number and the extension direction of the tenth portion 34B of the fourth data line 34 are not particularly limited and may be adjusted according to the design of the sub-pixel 4. In one embodiment of the present disclosure, the number of the data line 3 is calculated based on the number of the third portion 31A of the first data line 31, the fifth portion 32A of the second data line 32, the seventh portion 33A of the third data line 33 and the ninth portion 34A of the fourth data line 34 connected to the second driving unit D2.

In one embodiment of the present disclosure, as shown in FIG. 5, each sub-pixel 4 may comprise a transistor TFT, and the transistor TFT may be electrically connected to the corresponding scan line 2 and the corresponding data line 3 respectively, thereby driving the corresponding sub-pixel 4, but the present disclosure is not limited thereto. In one embodiment of the present disclosure, the number of the transistor TFT may be equal to the number of the sub-pixel 4, but the present disclosure is not limited thereto.

In the present disclosure, other detail features of the electronic device may be referred to those of FIG. 1A and FIG. 1B, and are not described again here.

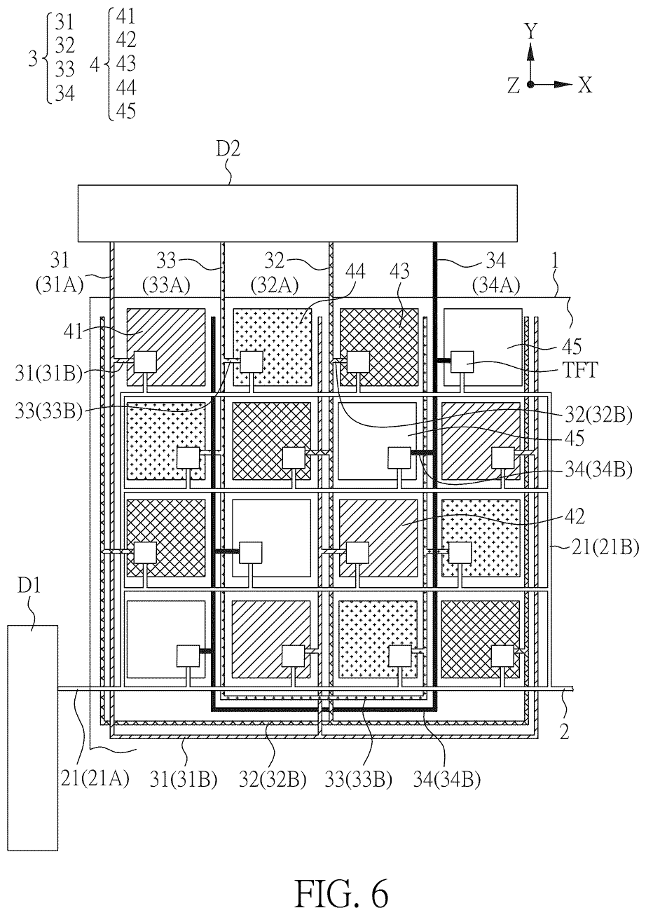

FIG. 6 is an enlarging schematic view of a part of an electronic device according to one embodiment of the present disclosure. The electronic device of FIG. 6 is similar to that of FIG. 5, except for the following differences. In addition, the same fill pattern represents sub-pixels with the same color in FIG. 6. Taking the sub-pixel on the top left side of FIG. 6 as the first sub-pixel as an example, the remaining sub-pixels with the same fill pattern can be the second sub-pixels, but the present disclosure is not limited thereto.

In one embodiment of the present disclosure, each pixel in the electronic device may comprise sub-pixels 4 arranged in a 4×4 array as shown in FIG. 6, but the present disclosure is not limited thereto, and the number and arrangement of the sub-pixels 4 may be adjusted according to the needs. In one embodiment of the present disclosure, in the second direction Y, the number of the sub-pixel 4 may be greater than the number of the scan line 2. For example, as shown in FIG. 6, there are 4 sub-pixels 4 and there is one scan line 2 in the second direction Y. Through the above design, the display quality of the electronic device can be improved. In the present disclosure, the number of the scan line 2 is calculated based on the number of one end of the scan line 2 connecting to the first driving unit D1.

In one embodiment of the present disclosure, as shown in FIG. 6, each sub-pixel 4 may comprise a transistor TFT, and the transistor TFT may be electrically connected to the corresponding scan line 2 and the corresponding data line 3 respectively, thereby driving the corresponding sub-pixel 4, but the present disclosure is not limited thereto. In one embodiment of the present disclosure, the number of the transistor TFT may be equal to the number of the sub-pixel 4, but the present disclosure is not limited thereto.

In the present disclosure, other detail features of the electronic device may be referred to those of FIG. 5, and are not described again here.

In the present disclosure, the display effect of the electronic device can be improved by disposing a plurality of sub-pixels receiving the same scan signal and the same data signal in one pixel and making the sub-pixels have the same color.

The above specific embodiments should be interpreted as merely illustrative and not limiting the rest of the present disclosure in any way.

Although the present disclosure has been explained in relation to its embodiment, it is to be understood that many other possible modifications and variations can be made without departing from the spirit and scope of the disclosure as hereinafter claimed.

1. An electronic device, comprising:
a substrate;
a scan line disposed on the substrate and used to output a first signal;
a first data line disposed on the substrate and intersecting with the scan line, wherein the first data line is used to output a second signal;
a first sub-pixel disposed on the substrate and receiving the first signal and the second signal; and
a second sub-pixel disposed on the substrate and receiving the first signal and the second signal,
wherein a color of the first sub-pixel is the same as a color of the second sub-pixel.

2. The electronic device of claim 1, further comprising a third sub-pixel disposed on the substrate and locating between the first sub-pixel and the second sub-pixel, wherein a color of the third sub-pixel is different from the color of the first sub-pixel.

3. The electronic device of claim 2, further comprising a second data line disposed on the substrate and intersecting with the scan line, wherein the second data line is used to output a third signal, and the third sub-pixel receives the first signal and the third signal.

4. The electronic device of claim 3, further comprising:
a third data line disposed on the substrate and intersecting with the scan line, wherein the third data line is used to output a fourth signal; and
a fourth sub-pixel disposed on the substrate and locating between the first sub-pixel and the second sub-pixel, wherein the fourth sub-pixel receives the first signal and the fourth signal.

5. The electronic device of claim 4, wherein a color of the fourth sub-pixel is different from the color of the first sub-pixel, and the color of the fourth sub-pixel is different from the color of the third sub-pixel.

6. The electronic device of claim 5, further comprising:
a fourth data line disposed on the substrate and intersecting with the scan line, wherein the fourth data line is used to output a fifth signal; and
a fifth sub-pixel disposed on the substrate and locating between the first sub-pixel and the second sub-pixel, wherein the fifth sub-pixel receives the first signal and the fifth signal.

7. The electronic device of claim 6, wherein a color of the fifth sub-pixel is different from the color of the first sub-pixel, the color of the fifth sub-pixel is different from the color of the third sub-pixel, and the color of the fifth sub-pixel is different from the color of the fourth sub-pixel.

8. The electronic device of claim 1, wherein a length of the first sub-pixel is greater than or equal to 0.1 mm and less than or equal to 10 mm in an extension direction of the scan line.

9. The electronic device of claim 8, wherein the length of the first sub-pixel is greater than or equal to ⅙ mm and less than or equal to 5 mm in the extension direction of the scan line.

10. The electronic device of claim 9, wherein the length of the first sub-pixel is greater than or equal to ⅓ mm and less than or equal to 3 mm in the extension direction of the scan line.

11. The electronic device of claim 1, further comprising:
a plurality of scan lines disposed on the substrate and extending along a first direction, wherein the plurality of scan lines comprise the scan line;
a plurality of data lines disposed on the substrate, extending along a second direction and intersecting with the plurality of scan lines, wherein the first direction is different from the second direction, and the plurality of data lines comprise the first data line; and
a plurality of sub-pixels disposed on the substrate and comprising the first sub-pixel and the second sub-pixel,
wherein the plurality sub-pixels are arranged in an array, and a number of the plurality of sub-pixels is greater than a number of the plurality of data lines in the first direction.

12. The electronic device of claim 11, further comprising a plurality of transistors respectively electrically connected to the plurality of scan lines and the plurality of data lines, wherein a number of the plurality of transistors is less than a number of the plurality of sub-pixels.

13. The electronic device of claim 11, further comprising a plurality of transistors respectively electrically connected to the plurality of scan lines and the plurality of data lines, wherein a number of the plurality of transistors is equal to a number of the plurality of sub-pixels.

14. The electronic device of claim 11, further comprising a driving unit, wherein the number of the plurality of data lines is calculated based on the number of one ends of the plurality of data lines connected to the driving unit.

15. The electronic device of claim 11, wherein the number of the plurality of sub-pixels is greater than a number of the plurality of scan lines in the second direction.

16. The electronic device of claim 15, further comprising another driving unit, wherein the number of the plurality of scan lines is calculated based on the number of one ends of the plurality of scan lines connected to the another driving unit.

17. The electronic device of claim 1, wherein the scan line comprises a first portion and a second portion connecting to the first portion, wherein the first portion is electrically connected to a first driving unit, and the second portion is electrically connected to the first sub-pixel and the second sub-pixel.

18. The electronic device of claim 1, wherein the first data line comprises a third portion and a fourth portion connecting to the third portion, wherein the third portion is electrically connected to a second driving unit, and the fourth portion is electrically connected to the first sub-pixel and the second sub-pixel.

19. The electronic device of claim 1, wherein the first sub-pixel and the second sub-pixel are electrically connected through a first connection line.

20. The electronic device of claim 19, wherein the second signal is transmitted from the first sub-pixel to the second sub-pixel through the first connection line.
